(19) United States
(12) Patent Application Publication
(10) Pub. No.: US 2008/0254635 A1
(43) Pub. Date: Oct. 16, 2008

(54) Method for Accelerated Etching of Silicon

(76) Inventors: Hubert Benzel, Pliezhausen (DE); Stefan Pinter, Reutlingen (DE); Christoph Schelling, Stuttgart (DE); Tjalf Pirk, Leonberg (DE); Julian Gonska, Reutlingen (DE); Frank Klopf, Waldbuettelbrunn (DE); Christina Leinenbach, Ensdorf (DE)

Correspondence Address: KENYON & KENYON LLP, ONE BROADWAY, NEW YORK, NY, 10004, US

(21) Appl. No.: 12/067,569

(22) PCT Filed: Sep. 18, 2006
(86) PCT No.: PCT/EP2006/066442

§ 371 Date: Jun. 11, 2008

(30) Foreign Application Priority Data
Sep. 30, 2005 (DE) 10 2005 047 081.5

(51) Int. Cl. H01L 21/306

(52) U.S. Cl. 438/705; 216/79; 257/E21.215

(57) ABSTRACT

A method for the plasma-free etching of silicon using the etching gas ClF₃ or XeF₂ and its use are provided. The silicon is provided having one or more areas to be etched as a layer on the substrate or as the substrate material itself. The silicon is converted into the mixed semiconductor SiGe by introducing germanium and is etched by supplying the etching gas ClF₃ or XeF₂. The introduction of germanium and the supply of the etching gas ClF₃ or XeF₂ may be performed at the same time or alternatingly. In particular, it is provided that the introduction of germanium be performed by implanting germanium ions in silicon.

### FIELD OF THE INVENTION

The present invention relates to a method for plasma-free etching of silicon using the etching gas ClF₃ or XeF₂ and its use.

### BACKGROUND INFORMATION

In semiconductor technology, etching procedures are among the most essential processing technologies for the targeted removal of materials. The etching of silicon is a known and important processing step both in electronic circuit technology and also in microsystem technology. However, it is fundamentally different in principle that the manufacture of an electronic circuit typically represents a planar problem, while micromechanical components typically are three-dimensional, i.e., the structuring depth is unequally pronounced. The etching of defined, in particular spatially narrow areas in depth is therefore among the fundamental technologies, in particular in microsystem technology. A demand for an etching method having greater etching speed results therefrom.

A deep etching method for silicon is described in German Published Patent Application No. 42 41 045, with the aid of which deep trenches having vertical walls may be produced in a silicon substrate, for example. Deposition steps, in which a Teflon-like polymer is deposited on the side wall, and fluorine-based etching steps, which are isotropic per se and are made locally anisotropic by driving the side wall polymer forward during the etching, alternate with one another. Although deep trenches having vertical walls may thus be achieved in a controlled and reproducible way, shortening the time of the etching procedure is desirable.

On the other hand, it is described in German Patent Application No. 10 2004 036 803.1 that the mixed semiconductor silicon-germanium (SiGe) can be used as the material to be removed in a micromechanical component on a substrate. The sacrificial layer may be made of SiGe here, which is typically deposited on the substrate via a CVD process (“chemical vapor deposition”). The actual structure layer is produced and structured on this sacrificial layer. By controlled removal of the sacrificial layer, a freestanding structure is produced thereon. Chlorine trifluoride (ClF₃) is preferably suggested as the etching gas, the etching gas SiGe etching highly selectively in relation to Si. However, refining this technology for etching silicon is neither discussed nor suggested.

### SUMMARY

Example embodiments of the present invention provide an etching method for silicon having a high etching rate and the use of such a method.

The etching method according to example embodiments of the present invention and its use have the advantage that very rapid etching of silicon without plasma is made possible. Even great etching depths may thus be achieved in an accelerated manner and the required etching time may therefore be significantly shortened. The method reduces the manufacturing costs for chips having pronounced depth structuring in this manner.

The method is suitable in particular for etching structures which are very narrow laterally, because fine, spatially selective etching is ensured.

Exemplary embodiments of the present invention are explained in greater detail on the basis of the drawings and the following description.

### BRIEF DESCRIPTION OF THE DRAWINGS

FIG. 1 shows an etching method for silicon according to an example embodiment of the present invention,

FIG. 2 shows an etching method according to an example embodiment of the present invention, and

FIGS. 3a and 3b show an etching method according to an example embodiment of the present invention.

### DETAILED DESCRIPTION

The method according to example embodiments of the present invention is based on the feature that the mixed semiconductor SiGe may be etched significantly more rapidly than Si. In addition, the superior higher etching rate for SiGe already occurs with a small proportion of germanium, for example, already from 3% germanium.

Therefore, for plasma-free etching of silicon having one or more areas to be etched, it is provided that the silicon be converted into the mixed semiconductor SiGe by introducing germanium and etched by supplying the etching gas ClF₃ or XeF₂. The method very advantageously allows the introduction of germanium and the supply of the etching gas ClF₃ or XeF₂ to be performed at the same time or, if needed, also alternatingly. In both cases, it is possible to introduce germanium selectively only at the areas of the silicon to be etched.

The variations of the general method will now be explained on the basis of examples. Although the silicon is provided as the substrate material itself in the examples, it may also be provided as a layer on a substrate in principle. In any case, the substrate is positioned during the method in a processing chamber known to those skilled in the art.

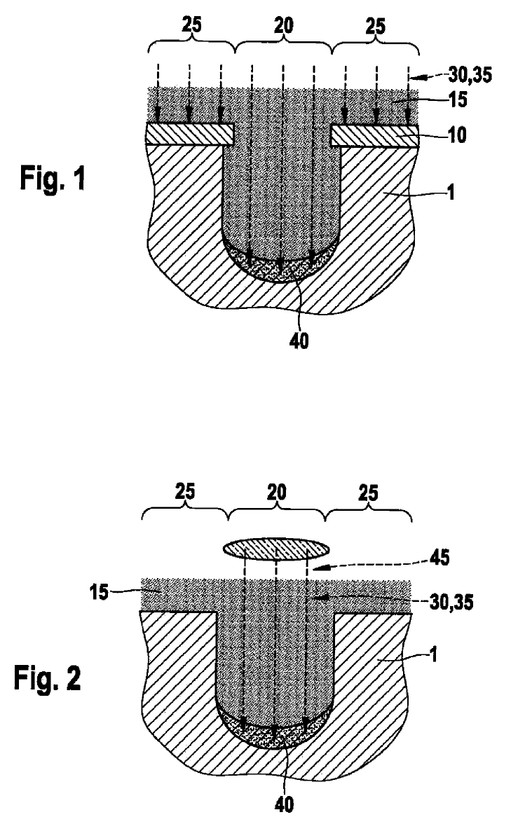

FIG. 1 shows a method according to an example embodiment of the present invention. Substrate 1 to be etched is made of silicon and has a mask 10, as is recognizable from FIG. 1. Etching gas ClF₃ 15 is continuously supplied to substrate 1, i.e., the substrate is continuously in contact with etching gas 15. Area 20 to be etched is unprotected by mask 10, while area 25 not to be etched is protected. Germanium 30, 35 is introduced here by implanting germanium ions 35, which act continuously on substrate 1 essentially vertically. Because of cited mask 10, germanium ions 35 are only incident on the silicon on areas 20 to be etched, in which germanium ions 35 are implanted and silicon 5 is thus converted into SiGe 40. The silicon enriched using Ge 30, 35 is etched spontaneously and at high speed by continuously surrounding etching medium ClF₃ 15. The deeper-lying areas of the silicon are exposed by the etching, and are in turn subjected to Ge ions 35. These areas are also enriched with Ge 30, 35 and etched.

The introduction of germanium 30, 35 and the supply of etching gas ClF₃ 15 to substrate 1 in the processing chamber also occur at the same time in an exemplary embodiment according to FIG. 2. However, the conversion of the silicon into SiGe 40 by selective introduction of germanium 30, 35 only on areas 20 to be etched is achieved using another means: instead of a mask 10 of substrate 1, only areas 20 of the silicon to be etched are traced using a focused germanium ion beam 45 and thus enriched with Ge ions 35. These areas are immediately etched by ClF₃ etching gas 15 provided in the processing chamber and are enriched again by Ge ions 35 in the next pass of germanium ion beam 45 and then etched deeper. In this exemplary embodiment, the high selectivity of the etching procedure of SiGe 40 to Si is exploited. This etching variant is slower due to the serial character than in the first exemplary embodiment, but this disadvantage is more than compensated for by the flexibility for small quantities of substrates 1 to be processed. In particular, mask-free structuring is advantageously achieved by this variant.

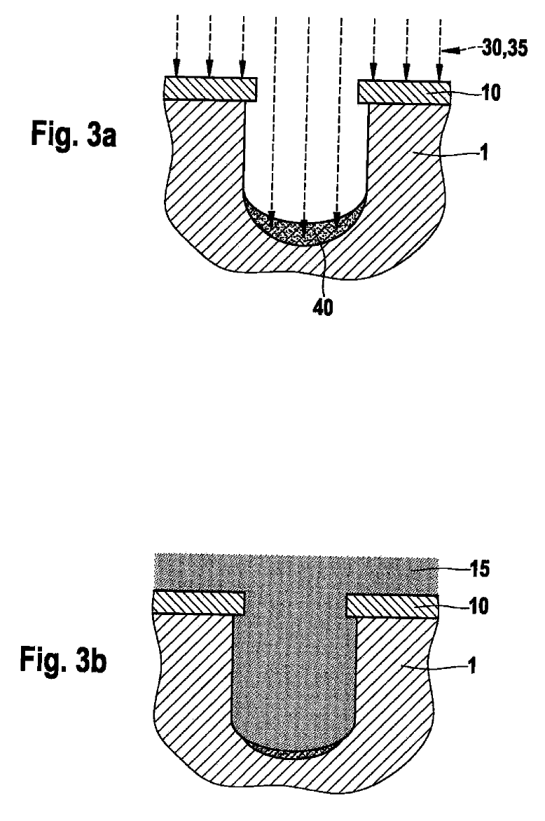

A further exemplary embodiment results from alternatingly introducing germanium 30, 35 into the silicon and introducing etching gas ClF₃ 15, i.e., etching using ClF₃ 15. As shown in FIG. 3a, silicon substrate 1 is masked as in the first exemplary embodiment and Ge ions 35 therefore only reach the unmasked areas of the silicon and convert the silicon into SiGe 40 at these points. However, no ClF₃ etching gas 15 has been introduced in this state or is present in the processing chamber, because of which etching does not occur. The introduction of Ge 30, 35 is ended or interrupted. For example, the ion source may be turned off or covered for this purpose. Subsequently, etching gas ClF₃ 15 is supplied into the processing chamber and thus to substrate 1 and previously produced SiGe 40 is etched (FIG. 3b). After the etching procedure, the surface is again formed by non-enriched silicon. The processing chamber is preferably evacuated to begin again with the introduction of Ge 30, 35. The two partial processes thus alternate cyclically. Moreover, this exemplary embodiment may also be modified such that mask 10 is dispensed with and instead focused ion beam 45 is used.

All described exemplary embodiments may be used for manufacturing substrates 1 in particular having deep structures such as through holes, trenches, or cavities in silicon. Moreover, the etching gas ClF₃ may be replaced by XeF₂ in all exemplary embodiments.

The penetration into the depth of silicon substrate 1 up into the vias or partition trenches introduced in substrate 1 is also made possible, which is not possible using the layered application of SiGe mixed semiconductors known from the related art. Cavities may thus be produced without the generally known edge loss of KOH etching, for example.

All micromechanical sensors offer interesting possible applications in principle. In addition, because of the accelerated etching, the method is also suitable for cutting up substrates 1, in particular for substrates 1 having a non-rectangular shape, such as needle-shaped or circular substrates. Finally, the method may preferably be used for cutting up substrates 1 having open structures, which only allow dry cutting.

1-8. (canceled)

9. A method for plasma-free etching of silicon having at least one area to be etched, existing as at least one of (a) a layer on a substrate and (b) a substrate material itself, comprising:
converting the silicon into a mixed semiconductor SiGe by introducing germanium; and
etching the silicon by supplying at least one of (a) CIF₃ and XeF₂ as an etching gas.

10. The method according to claim 9, wherein the introduction of germanium and the supplying of the etching gas are performed at a same time.

11. The method according to claim 9, wherein the introduction of germanium and the supply of the etching gas are performed alternatingly in time.

12. The method according to claim 9, wherein the introduction of germanium is performed by implanting germanium ions in silicon.

13. The method according to claim 9, wherein the conversion of the silicon into SiGe is performed by selective introduction of germanium only at the area to be etched.

14. The method according to claim 13, wherein the selective introduction of germanium into the silicon is achieved by a mask of the silicon.

15. The method according to claim 13, wherein the selective introduction of germanium into the silicon is achieved by focused germanium ion beams.

16. A method for at least one of (a) producing deep structures in silicon and (b) cutting up a substrate, comprising:
plasma-free etching of the silicon having at least one area to be etched, existing as at least one of (a) a layer on the substrate and (b) a substrate material itself including:
converting the silicon into a mixed semiconductor SiGe by introducing germanium; and
etching the silicon by supplying at least one of (a) CIF₃ and XeF₂ as an etching gas.

17. The method according to claim 16, wherein the deep structures include at least one of (a) through holes and (b) trenches.
